(19) United States
(12) Patent Application Publication
(10) Pub. No.: US 2016/0210072 A1
(43) Pub. Date: Jul. 21, 2016

(54) CONTROLLER AND MEMORY SYSTEM

(71) Applicant: Kabushiki Kaisha Toshiba, Minato-ku (JP)

(72) Inventor: Hiroki AIZAWA, Yokohama (JP)

(73) Assignee: Kabushiki Kaisha Toshiba, Minato-ku (JP)

(21) Appl. No.: 14/796,250

(22) Filed: Jul. 10, 2015

Related U.S. Application Data
(60) Provisional application No. 62/103,792, filed on Jan. 15, 2015.

(51) Int. Cl. G06F 3/06; G11C 5/14

(52) U.S. Cl. CPC G06F 3/0625; G11C 5/147; G06F 3/0659; G06F 3/0661; G06F 3/0679

(57) ABSTRACT

According to one embodiment, there is provided a controller including a memory control circuit, a host interface, and a power control circuit. The memory control circuit controls a nonvolatile semiconductor memory. The host interface performs data-format conversion between data of a host and data of the memory control circuit and generates an internal signal according to a low power instruction signal received from the host. The power control circuit performs at least one of a clock stop and a power shutdown to a power supply area including at least part of the host interface according to the internal signal received from the host interface and performs, to the power supply area, at least one of a power restoration and a clock resumption according to the low power instruction signal received from the host.

### CROSS-REFERENCE TO RELATED APPLICATIONS

This application is based upon and claims the benefit of priority from U.S. Provisional Application No. 62/103,792, filed on Jan. 15, 2015; the entire contents of which are incorporated herein by reference.

### FIELD

Embodiments described herein relate generally to a controller and a memory system.

### BACKGROUND

A memory system is connected to a host to function as an external storage medium for the host. The host may desire to have the memory system operate with low power consumption. At this time, it is desired that a controller in the memory system perform control for lowering power according to an instruction from the host.

### BRIEF DESCRIPTION OF THE DRAWINGS

FIG. 1 is a block diagram showing the configuration of a memory system according to a first embodiment;

FIG. 2 is a timing chart showing the operation of the memory system according to the first embodiment;

FIG. 3 is a block diagram showing the configuration of a memory system according to a second embodiment;

FIG. 4 is a timing chart showing the operation of the memory system according to the second embodiment;

FIG. 5 is a block diagram showing the configuration of a memory system according to a third embodiment;

FIG. 6 is a block diagram showing the configuration of a host interface (hereinafter a host I/F) in the third embodiment;

FIG. 7 is a timing chart showing the operation of the memory system according to the third embodiment;

FIG. 8 is a block diagram showing the configuration of a memory system according to a fourth embodiment;

FIG. 9 is a block diagram showing the configuration of a host I/F in the fourth embodiment;

FIG. 10 is a block diagram showing the configuration of a memory system according to a fifth embodiment; and

FIG. 11 is a block diagram showing the configuration of a host I/F in the fifth embodiment.

### DETAILED DESCRIPTION

In general, according to one embodiment, there is provided a controller including a memory control circuit, a host interface, and a power control circuit. The memory control circuit controls a nonvolatile semiconductor memory. The host interface performs data-format conversion between data of a host and data of the memory control circuit and generates an internal signal according to a low power instruction signal received from the host. The power control circuit performs at least one of a clock stop and a power shutdown to a power supply area including at least part of the host interface according to the internal signal received from the host interface and performs, to the power supply area, at least one of a power restoration and a clock resumption according to the low power instruction signal received from the host.

Exemplary embodiments of a memory system will be explained below in detail with reference to the accompanying drawings. The present invention is not limited to the following embodiments.

### First Embodiment

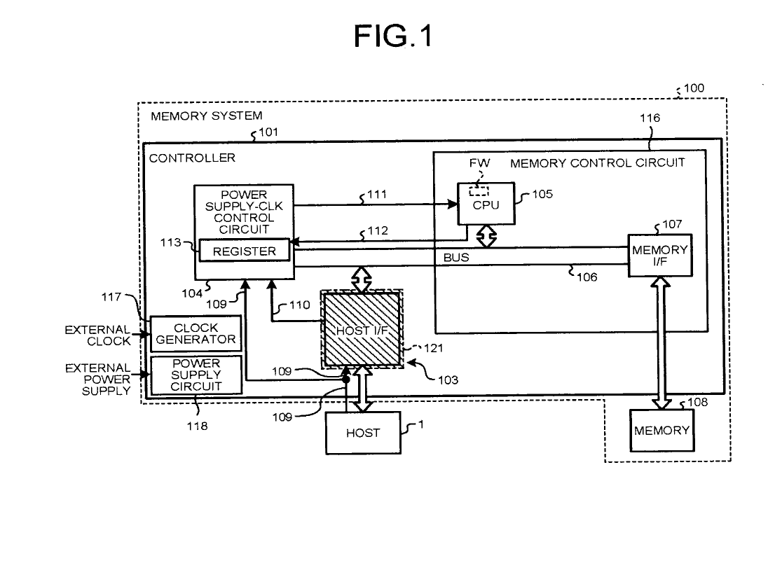

A memory system 100 according to the first embodiment will be described using FIG. 1. FIG. 1 is a block diagram showing the configuration of the memory system 100. The memory system 100 is connected to a host 1 and functions as an external storage medium for the host 1. The memory system 100 is, for example, a flash memory for embedded use compliant with UFS (Universal Flash Storage) Standard, eMMC (embedded Multi Media Card) Standard, or the like, or an SSD (Solid State Drive). The host 1 is, for example, a personal computer, a mobile telephone, an imaging device, or the like.

The memory system 100 has a nonvolatile semiconductor memory 108 and a controller 101. The nonvolatile semiconductor memory 108 is, for example, a NAND flash memory.

The nonvolatile semiconductor memory 108 has a memory cell array having multiple memory cells arranged in a matrix. Each individual memory cell can store a multiple value using an upper page and a lower page. The nonvolatile semiconductor memory 108 is configured with multiple blocks that are units for data erasure arranged. Further, each block is formed of multiple pages. Each page is a unit for data write and read. The nonvolatile semiconductor memory 108 is formed of, e.g., multiple memory chips.

The nonvolatile semiconductor memory 108 stores, for example, management information of the memory system 100 and user data therein. The management information of the memory system 100 includes a logical-physical conversion table (L2P table).

The logical-physical conversion table (L2P table) is address conversion information which maps logical addresses (LBA: Logical Block Address) that the host 1 uses when accessing the memory system 100 to physical addresses in the nonvolatile semiconductor memory 108 (each=a block address+a page address+an intra-page storage location).

The controller 101 has a memory control circuit 116, a host interface (hereinafter a host I/F) 103, a power supply-CLK control circuit (power control circuit) 104, a clock generator 117, and a power supply circuit 118. The memory control circuit 116 has a CPU 105, a memory I/F 107, and wiring 109. The CPU 105, memory I/F 107, host I/F 103, and power supply-CLK control circuit 104 are connected to each other via a bus 106.

The CPU 105 controls the memory system 100 overall. The CPU 105 includes firmware FW and performs control operation according to the firmware FW.

The host I/F 103 is an interface to connect to the host 1. For example, when receiving data from the host 1, the host I/F 103 data-format converts the received data from a format for the host 1 to a format for the bus 106. For example, the host I/F 103 performs data-format conversion from a format for the host 1 to a format for the bus 106 so that the memory control circuit 116 can process data for the host 1. The host I/F 103 transfers the data-format converted data to the nonvolatile semiconductor memory 108 via the bus 106 and memory I/F 107. The nonvolatile semiconductor memory 108 stores the transferred data.

Note that data-format conversion in the host I/F 103 refers to, e.g., conversion between packet data for the host 1 such as MemRd or MemWr compliant with PCI Standard and data for the bus 106 compliant with AXI Standard.

The memory I/F 107 reads/writes data and management information from/into the nonvolatile semiconductor memory 108.

For example, when a read operation is requested by the host 1, the memory I/F 107 reads data from the nonvolatile semiconductor memory 108 and transfers the read data to the host I/F 103 via the bus 106. The host I/F 103 data-format converts the data transferred from the memory I/F 107 from the format for the bus 106 to the format for the host 1. The host T/F 103 transfers (transmits) the data-format converted data to the host 1.

Or, for example, when a write operation is requested by the host 1, the host I/F 103 data-format converts data received from the host 1 from the format for the host 1 to the format for the bus 106. The host I/F 103 transfers the data-format converted data to the memory control circuit 116 via the bus 106. The memory I/F 107 writes data supplied from the host I/F 103 into the nonvolatile semiconductor memory 108.

The clock generator 117 receives reference pulses from the outside (e.g., the host 1) and generates a clock (system clock) based on the reference pulses. The clock generator 117 supplies the generated clock to each of the memory control circuit 116, the host I/F 103, and the power supply-CLK control circuit 104.

The power supply circuit 118 receives a plurality of power supplies V1, V2 from the outside (e.g., the host 1). The power supply circuit 118 supplies the plurality of power supplies V1, V2 to each of the memory control circuit 116, the host I/F 103, and the power supply-CLK control circuit 104. The power supply V1 is a power supply of, e.g., 1.8 V. The power supply V2 is a power supply of, e.g., 1.1 V.

The host 1 may desire to have the memory system 100 operate with low power consumption. At this time, it is desired that the memory system 100 perform operation for lowering power according to an instruction from the host 1.

The memory system 100 has a low power consumption mode and a normal mode as operation modes. The low power consumption mode is one in which the memory system 100 operates with low power consumption as compared with the normal mode. The wiring 109 can connect the host I/F 103 to the host 1. The host I/F 103 can receive a low power instruction signal from the host 1 via the wiring 109. The low power instruction signal is, e.g., a side band signal and, when at an active level (H level), instructs to go into the low power consumption mode, that is, to reduce power and, when at a non-active level (L level), instructs to return from the low power consumption mode to the normal mode. The wiring 109 includes, e.g., lines. The low power instruction signal may be packet data like a command packet instead of being a side band signal. In this case, the wiring 109 includes, e.g., bus lines.

For example, when desiring to have the memory system 100 operate with low power consumption, the host 1 transmits the low power instruction signal of the active level (H level) to the memory system 100. The memory system 100 receives the low power instruction signal of the active level and, according to the low power instruction signal of the active level, performs control to switch the operation mode from the normal mode to the low power consumption mode.

Or, for example, when desiring to have the memory system 100 return to the normal mode, the host 1 transmits the low power instruction signal of the non-active level (L level) to the memory system 100. The memory system 100 receives the low power instruction signal of the non-active level and, according to the low power instruction signal of the non-active level, performs control to make the operation mode return from the low power consumption mode to the normal mode.

Each time data is transferred between the memory system 100 and the host 1, the data goes through the host I/F 103. Further, in order to allow the memory system 100 to communicate with the host 1 at high speed, it is effective to make the host I/F 103 compliant with a high-speed interface standard. The high-speed interface standard is, for example, PCI Express (hereinafter called PCIE). In this case, the power consumption of the host I/F 103 is thought to account for a large proportion of the power consumption of the memory system 100.

As a method of having the memory system 100 in the low power consumption mode operate with low power consumption, one can think of stopping clock supply to the host. I/F 103. That is, when the CPU 105 writes a control value to instruct to go into the low power consumption mode into a register 113, clock supply from the clock generator 117 to the host I/F 103 is stopped to lower the power consumption of the memory system 100. In this case, even if clock supply to the host I/F 103 is stopped, power supply from the power supply circuit 118 to the host I/F 103 is continued, and hence it tends to be difficult to lower the power consumption of the memory system 100 to a required level.

Accordingly, in the present embodiment, in the memory system 100, when receiving the low power instruction signal of the active level (H level) from the host 1, in addition to stopping clock supply to the host I/F 103, power supply is shut down to further reduce the power consumption of the memory system 100.

Specifically, in the memory system 100, the controller 101 further has wiring 110, wiring 111, and wiring 112.

The wiring 110 connects the host I/F 103 and the power supply-CLK control circuit 104. Thus, when the host I/F 103 goes into a state where power supply can be shut down, the wiring 110 can transmit a low power internal instruction signal from the host I/F 103 to the power supply-CLK control circuit (power control circuit) 104.

The wiring 109 connects the host 1 and the power supply-CLK control circuit 104. Thus, where power supply to the host I/F 103 is shut down, the power supply-CLK control circuit 104 can receive the low power instruction signal of the active level from the host 1 via the wiring 109.

The wiring 111 connects the power supply-CLK control circuit 104 and the CPU 105. Thus, when the host I/F 103 goes into a state where power supply can be shut down, the wiring 111 can transmit an interrupt signal from the power supply-CLK control circuit 104 to the CPU 105.

The wiring 112 connects the CPU 105 and the register 113. Thus, the CPU 105 can write a desired control value into the register 113 via the wiring 112. Note that the wiring 112 may be included in the bus 106. That is, the CPU 105 may write a desired control value into the register 113 via the bus 106.

The host I/F 103 includes a state machine and has the state machine hold the state of the host I/F 103. The host I/F 103 generates the low power internal instruction signal according to the state of the host I/F 103 held in the state machine. The host I/F 103 supplies the generated low power internal instruction signal to the power supply-CLK control circuit 104 via the wiring 110.

When receiving the low power internal instruction signal instructing to reduce power via the wiring 110, the power supply-CLK control circuit 104 performs a clock stop and power shutdown to the host I/F 103 according to the low power internal instruction signal. That is, the power supply-CLK control circuit 104 controls the clock generator 117 to stop clock supply to the host I/F 103 while continuing clock supply to the power supply-CLK control circuit 104 and the memory control circuit 116. Further, the power supply-CLK control circuit 104 controls the power supply circuit 118 to shut down power supply to the host I/F 103 while continuing power supply to the power supply-CLK control circuit 104 and the memory control circuit 116.

The power supply-CLK control circuit 104 can receive the low power instruction signal from the host 1 via the wiring 109 while power supply to the host I/F 103 is shut down. When receiving the low power instruction signal instructing to restore, the power supply-CLK control circuit 104 restores power supply and resumes clock supply to the host I/F 103 according to the low power internal instruction signal. That is, the power supply-CLK control circuit 104 controls the power supply circuit 118 to restore power supply to the host I/F 103. The power supply-CLK control circuit 104 controls the clock generator 117 to resume clock supply to the host I/F 103.

For example, the power supply-CLK control circuit 104 has the register 113 for power control. A first control value is written by the CPU 105 into the register 113 via the wiring 112. The first control value is one to instruct to perform clock stop and power shutdown. The power supply-CLK control circuit 104, according to the first control value being written into the register 113, perform a clock stop and power shutdown to the host I/F 103.

The controller 101 performs a clock stop and power shutdown to the host I/F 103 according to the low power instruction signal (of the active level) instructing to reduce power.

For example, the host I/F 103 receives the low power internal instruction signal of the active level from the host 1 via the wiring 109. According to the host 1 transitioning from a normal state (L0 state) to a low power state (L1 state), the host I/F 103 switches the state of the host I/F 103 held in the state machine from a normal state (L0 state) to transition preparation (L1.0 state). The host I/F 103, according to the low power internal instruction signal of the active level, switches the state of the host I/F 103 held in the state machine from a transition state (L1.0 state) via a transition state (L1.2Entry state) to a low power state (L1.2Idle state). The state of the host I/F 103 held in the state machine is a state defined according to PCIE Standard. For example, at the timing when it transitions from the transition state (L1.0 state) to the transition state (L1.2Entry state), the host I/F 103 starts a time count by a timer (not shown) and, when a predetermined time has elapsed, switches the state from the transition state (L1.2Entry state) to the low power state (L1.2Idle state). At the same time, the host I/F 103 realizes the progress status of data transfer processing.

The host I/F 103 determines whether all first, second, and third conditions have been met. The first condition includes the low power instruction signal being at the active level. The second condition includes the completion of the host I/F 103 transitioning to the low power state (L1.2Idle state). The third condition includes the completion of transfer processing by the host I/F 103.

If all the first, second, and third conditions have been met, the host I/F 103 generates the low power internal instruction signal (of the active level) instructing to reduce power. The host I/F 103 supplies the low power internal instruction signal instructing to reduce power to the power supply-CLK control circuit 104 via the wiring 110.

The power supply-CLK control circuit 104 supplies an interrupt signal to the CPU 105 via the wiring 111 according to the low power internal instruction signal instructing to reduce power. The CPU 105 writes the first control value (e.g., a bit value of 0) into the register 113 via the wiring 112 according to the interrupt signal. The power supply-CLK control circuit 104 performs a clock stop and power shutdown to the host I/F 103 according to the first control value being written into the register 113. That is, the control circuit 104 performs a clock stop and power shutdown to a power supply area 121 indicated by oblique hatching in FIG. 1.

The controller 101 restores power supply and resumes clock supply to the host I/F 103 according to the low power instruction signal (of the non-active level) instructing to restore.

For example, the power supply-CLK control circuit 104 receives the low power instruction signal of the non-active level from the host 1 via the wiring 109. The power supply-CLK control circuit 104 restores power supply and resumes clock supply to the host I/F 103 according to the low power instruction signal of the non-active level.

The host I/F 103 switches the state of the host I/F 103 held in the state machine according to PCIE Standard from the low power state (L1.2Idle state) via transition states (L1.2Exit state, L1.0 state, RECOVERY state) to the normal state (L0 state).

It should be noted that, although FIG. 1 illustrates the case where the controller 101 controls by one CPU 105, a plurality of CPUs may be used to increase speed. Further, the nonvolatile semiconductor memory 108 may be mounted in a package separate from that of the controller 101 or in the same package as the controller 101.

It is desirable that at least part of the power supply area 121 (the host I/F 103) that holds an initial setting value be constituted by a retention flip-flop (hereinafter a retention F/F) (or a retention SRAM) that holds the state before power supply was shut down. The retention F/F receives standby-operation power supply greatly lower than power supply in normal times from the power supply circuit 118 and can continue holding the setting value using the standby-operation power supply. Thus, on power supply restoration, the host I/F 103 can take over the setting value before the power shutdown to operate and hence does not need to perform initializing setting or the like on other registers and the like again after power supply restoration. However, because the retention F/F has the demerit that its layout area is larger, it is desirable to apply to a minimum number of registers and the like with which to not need to perform initializing setting or the like on registers and the like again at power supply restoration. For example, the state machine and control registers in the host I/F 103 may be constituted by retention F/Fs while the data path in the host. I/F 103 may be constituted by usual F/Fs (or usual SRAMs). Thus, on power supply restoration, the host I/F 103 can resume operating in the state before the power shutdown with suppressing an increase in layout area (that is, there is no need for re-linkup).

Further, it is desirable that cells to drive values after power supply restoration, called isolation cells, be placed between the power supply area 121 and the other. These can determine the values of circuits around the power supply area 121 at power supply restoration so as to prevent the malfunction of the circuits around the power supply area 121.

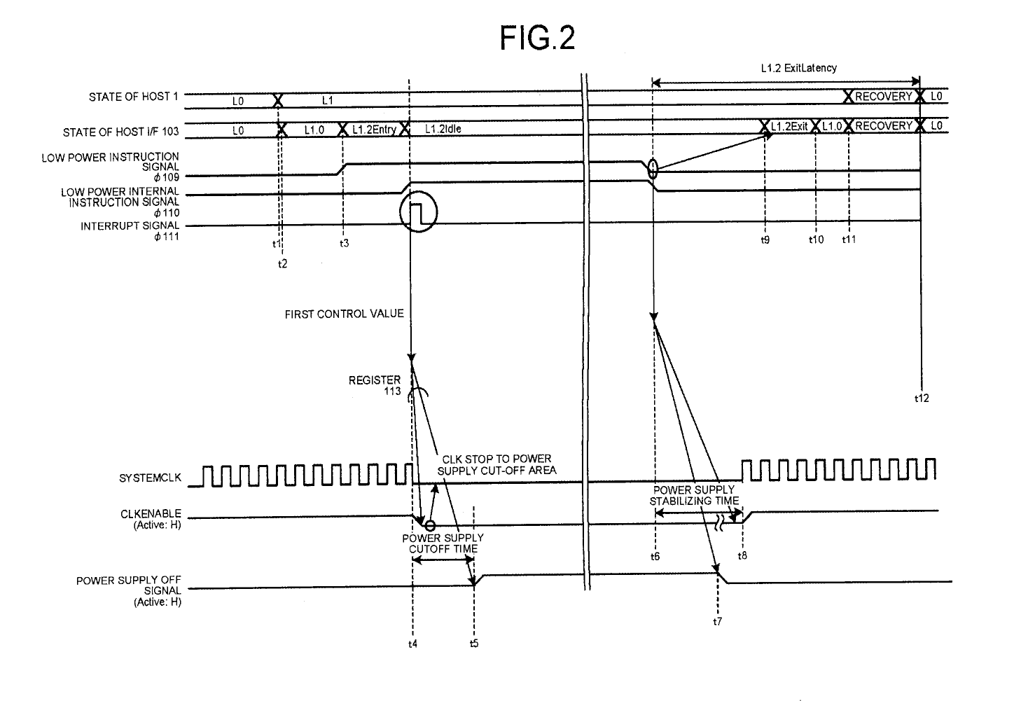

Next, the operation of the memory system 100 will be described using FIG. 2. FIG. 2 is a timing chart showing the operation of the memory system 100.

In FIG. 2, “STATE OF HOST 1” denotes the state of the host 1 managed on the host 1 side, which is a state defined according to PCIE Standard. “L0” denotes the normal state, which is a state where it operates synchronously with a high speed clock. “L1” denotes the low power state. “RECOVERY” denotes a transition state in a return from the low power state to the normal state.

“STATE OF HOST I/F 103” denotes the state of the host I/F 103 that the host I/F 103 has the state machine hold, which is a state defined according to PCIE Standard. “L0” denotes the normal state where it operates in a normal mode. “L1.2Idle state” denotes the low power state where it operates in a low power consumption mode. “L1.0” denotes a first-stage state in transition from the normal mode to the low power consumption mode or a second-stage state in return transition from the low power consumption mode to the normal mode. “L1.2Entry” denotes a second-stage state in transition from the normal mode to the low power consumption mode. “L1.2Exit” denotes a first-stage state in return transition from the low power consumption mode to the normal mode. “RECOVERY” denotes a third-stage state in return transition from the low power consumption mode to the normal mode.

“LOW POWER INSTRUCTION SIGNAL φ109” is a low power instruction signal that is transmitted from the host 1 to the memory system 100 and received by the host I/F 103 and/or the power supply-CLK control circuit 104 via the wiring 109. “LOW POWER INSTRUCTION SIGNAL φ109” is an active high signal and is at the H level when instructing to reduce power and at the L level when instructing to return to the normal state.

“LOW POWER INTERNAL INSTRUCTION SIGNAL φ110” is a low power internal instruction signal that is supplied from the host I/F 103 to the power supply-CLK control circuit 104 via the wiring 110. “LOW POWER INTERNAL INSTRUCTION SIGNAL φ110” is an active high signal and is at the H level when instructing to reduce power (that is, to go into the low power consumption mode) and at the L level when not instructing to reduce power.

“INTERRUPT SIGNAL φ111” is an interrupt signal that is supplied from the power supply-CLK control circuit 104 to the CPU 105 via the wiring 111. “INTERRUPT SIGNAL φ111” is at the H level to notify an interrupt when an instruction to reduce power (that is, to go into the low power consumption mode) occurs and is reset from the H level to the L level after the CPU 105 finishes writing the first control value into the register 113.

“SYSTEMCLK” is an internal clock generated by the clock generator 117 and supplied to the host I/F 103. Note that clock supply from the clock generator 117 to the power supply-CLK control circuit 104 and the memory control circuit 116 is steadily continued although not shown.

“CLKENABLE” is a clock enable signal supplied from the power supply-CLK control circuit 104 to the clock generator 117. “CLKENABLE” is a clock enable signal for the host I/F 103. “CLKENABLE” is an active high signal and is at the H level when instructing to supply the clock to the host I/F 103 and at the L level when instructing to stop clock supply to the host I/F 103. Although not shown, a clock enable signal for the power supply-CLK control circuit 104 supplied from the power supply-CLK control circuit 104 to the clock generator 117 and a clock enable signal for the memory control circuit 116 are kept at the active level (H level).

“POWER SUPPLY OFF SIGNAL” is a power supply OFF signal supplied from the power supply-CLK control circuit 104 to the power supply circuit 118. “POWER SUPPLY OFF SIGNAL” is a power supply OFF signal for the host I/F 103. “POWER SUPPLY OFF SIGNAL” is an active high signal and is at the H level when instructing to shut down power supply and at the L level when instructing to restore power supply. Although not shown, a power supply OFF signal for the power supply-CLK control circuit 104 supplied from the power supply-CLK control circuit 104 to the power supply circuit 118 and a power supply OFF signal for the memory control circuit 116 are kept at the non-active level (L level).

At timing t1, the host 1 switches the state of the host 1 from the normal state (L0 state) to the low power state (L1 state).

At timing t2, the memory system 100 switches the state of the host I/F 103 from the normal state (L0 state) to a first-stage transition state (L1.0 state) on the way to the low power state (L1.2Idle state).

At timing t3, the low power instruction signal φ109 transitions from “L” to “H”. This is an instruction from the host 1 to go into a low power state (L1.2 state) further deeper than the low power state (L1 state) of the host 1. At this time, the host I/F 103 transitions from the first-stage transition state (L1.0 state) to the second-stage transition state (L1.2Entry state).

At timing t4, when determining that data transfer processing in the host I/F 103 has finished, so that a power shutdown is possible, the host I/F 103 makes the low power internal instruction signal φ110 transition from “L” to “H”.

Here, if the low power instruction signal φ109 is used directly for a power shutdown, then power supply to the host I/F 103 is shut down before data transfer processing in the host I/F 103 finishes, so that data not yet transferred may be lost. Accordingly, at a power shutdown, the host I/F 103, receiving the low power instruction signal φ109, after determining that data transfer processing has finished and that thus a power shutdown to the host I/F 103 is possible, sets the low power internal instruction signal φ110 at the active level to have power shutdown.

The host I/F 103 supplies the low power internal instruction signal φ110 set at the active level (H level) to the power supply-CLK control circuit 104 via the wiring 110. When receiving the low power internal instruction signal φ110 of the active level, the power supply-CLK control circuit 104 generates the interrupt signal φ111 to notify the CPU 105 via the wiring 111. The CPU 105 writes the first control value (e.g., a bit value of 0) into the register 113 via the wiring 112 according to receiving the interrupt signal φ111. With this operation, it instructs to perform a clock stop and power shutdown to the host I/F 103.

The power supply-CLK control circuit 104 makes the clock enable signal CLKENABLE transition from “H” to “L” according to the first control value being written into the register 113. Thus, supply of the clock SYSTEMCLK from the clock generator 117 to the host I/F 103 is stopped. That is, a clock stop to the host I/F 103 is performed.

Further, the power supply-CLK control circuit 104 starts counting a power shutdown time at timing t4 using a counter (not shown). The power shutdown time has a predetermined time length (counter count value) in which power supply can be shut down stably after a clock stop.

At timing t5, the power supply-CLK control circuit 104 makes the power supply OFF signal transition from “L” to “H” according to the power shutdown time having elapsed. Thus, power supply from the power supply circuit 118 to the host I/F 103 is shut down. That is, a power shutdown to the host I/F 103 is performed.

At timing t6, the low power instruction signal φ109 transitions from “H” to “L”. This is an instruction from the host 1 to return from the low power state (L1.2 state) to the normal state (L0 state).

The power supply-CLK control circuit 104 receives the low power instruction signal φ109 of the non-active level (L level) from the host 1 via the wiring 109.

Further, the power supply-CLK control circuit 104 starts counting a power supply stabilizing time at timing t6 using a counter (not shown). The power supply stabilizing time has a predetermined time length (counter count value) in which clock supply can be resumed stably after power supply restoration (power supply can be stabilized after restoration).

At timing t7, the power supply-CLK control circuit 104 makes the power supply OFF signal for the host I/F 103 transition from “H” to “L” according to the low power instruction signal φ109 of the non-active level (L level). Thus, power supply from the power supply circuit 118 to the host I/F 103 is restored. That is, power restoration to the host I/F 103 is performed.

At timing t8, the power supply-CLK control circuit 104 makes the clock enable signal CLKENABLE transition from “L” to “H” according to the power supply stabilizing time having elapsed. Thus, supply of the clock SYSTEMCLK from the clock generator 117 to the host I/F 103 is resumed. That is, clock resumption to the host I/F 103 is performed.

At timing t9, the host I/F 103 switches the state of the host I/F 103 from the low power state (L1.2Idle state) to a first-stage transition state (L1.2Exit state) according to power restoration and clock resumption to the host I/F 303. Thus, the host I/F 103 goes out of the low power state (L1.2Idle state).

At timing t10, the host I/F 103 switches the state of the host I/F 103 from the first-stage transition state (L1.2Exit state) to a second-stage transition state (L1.0 state).

At timing t11, the host I/F 103 switches the state of the host I/F 103 from the second-stage transition state (L1.0 state) to a third-stage transition state (RECOVERY state).

At timing t12, the host I/F 103 switches the state of the host I/F 103 from the third-stage transition state (RECOVERY state) to the normal state (L0 state).

A time L1.2 ExitLatency from timing t6 to timing t12 is a restoration processing time from when an instruction to restore is received from the host 1 until the memory system 100 finishes restoration.

As described above, in the first embodiment, the power supply-CLK control circuit 104 in the memory system 100 can receive the low power instruction signal from the host 1 via the wiring 109 while power supply to the host I/F 103 is shut down. The power supply-CLK control circuit 104 performs power restoration and clock resumption to the host I/F 103 according to the low power instruction signal instructing to restore. Thus, even while power supply to the host I/F 103 is shut down, power restoration and clock resumption to the host I/F 103 can be performed according to the low power instruction signal from the host 1 instructing to restore.

It should be noted that, although FIG. 1 illustrates the case where the clock generator 117 and the power supply circuit 118 are provided in the controller 101, at least one of the clock generator 117 and the power supply circuit 118 may be provided outside the controller 101 and in the memory system 100. Or at least one of the clock generator 117 and the power supply circuit 118 may be provided outside the memory system 100.

Or when the host I/F 103 receives the low power internal instruction signal instructing to reduce power from the host 1, the power supply-CLK control circuit 104 may perform a power shutdown to the host I/F 103 without performing a clock stop to the host I/F 103. In this case, also during the period from timing t4 to timing t8 shown in FIG. 2, “SYSTEMCLK” is continued. That is, also during the period from timing t4 to timing t8 shown in FIG. 2, the supply of the clock SYSTEMCLK from the clock generator 117 to the host I/F 103 is continued.

Or when the host I/F 103 receives the low power internal instruction signal instructing to reduce power from the host 1, the power supply-CLK control circuit 104 may perform a clock stop to the host I/F 103 without performing a power shutdown to the host I/F 103. In this case, also during the period from timing t5 to timing t7 shown in FIG. 2, “POWER SUPPLY OFF SIGNAL” is kept at the non-active level. That is, also during the period from timing t5 to timing t7 shown in FIG. 2, power supply from the power supply circuit 118 to the host I/F 103 is continued.

### Second Embodiment

Next, a memory system 200 according to the second embodiment will be described. Description will be made below focusing on the differences from the first embodiment.

While in the first embodiment power supply to the power supply area 121 corresponding to the host I/F 103 is selectively shut down, in the second embodiment power supply to another power supply area 222 is also shut down.

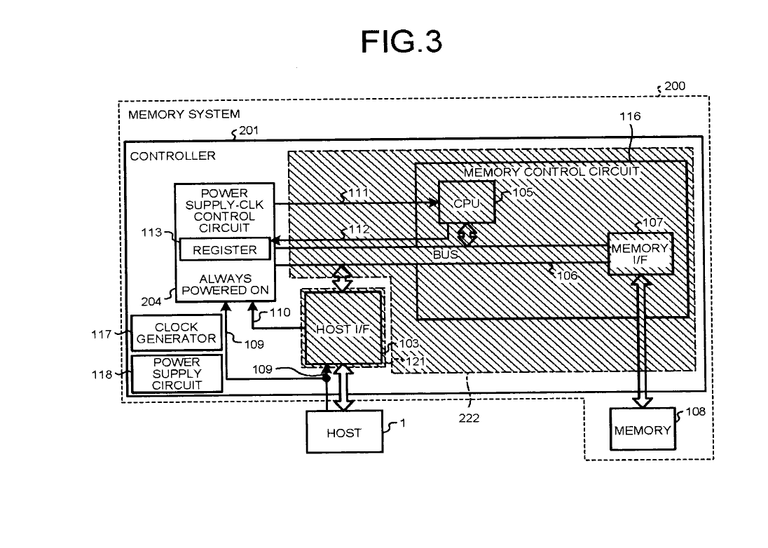

Specifically, as shown in FIG. 3, in a controller 201 of the memory system 200, a power supply-CLK control circuit 204 performs a clock stop and a power shutdown to the host I/F 103 and the memory control circuit 116 according to the low power internal instruction signal instructing to reduce power. FIG. 3 is a diagram showing the configuration of the memory system 200.

For example, the power supply-CLK control circuit 204 supplies an interrupt signal to the CPU 105 via the wiring 111 according to the low power internal instruction signal instructing to reduce power. The CPU 105 writes the first control value (e.g., a bit value of 0) into the register 113 via the wiring 112 according to the interrupt signal. The power supply-CLK control circuit 204 performs a clock stop and power shutdown to the host I/F 103 and the memory control circuit 116 according to the first. control value being written into the register 113. That is, it performs a clock stop and power shutdown to each of the power supply areas 121 and 222 indicated by oblique hatching in FIG. 3. The power supply area 222 includes the memory control circuit 116 and the bus 106.

Further, the power supply-CLK control circuit 204 performs power restoration and clock resumption to the host I/F 103 and the memory control circuit 116 according to the low power internal instruction signal instructing to restore.

For example, when receiving the low power instruction signal instructing to restore from the host 1, the power supply-CLK control circuit 204 performs power restoration to the memory control circuit 116 according to the low power instruction signal. Then the power supply-CLK control circuit 204 performs power restoration to the host I/F 103 and clock resumption to the host I/F 103 and the memory control circuit 116 according to the low power instruction signal.

It should be noted that it is desirable that at least part of the power supply area 222 (the memory control circuit 116) that holds an initial setting value be constituted by a retention F/F (or a retention SRAM) that holds the state before power supply was shut down. With this constitution, on power supply restoration, the host I/F 103 can take over the setting value before the power shutdown to operate and hence does not need to perform initializing setting or the like on other registers and the like again after power supply restoration.

Further, it is desirable that cells to drive values after power supply restoration, called isolation cells, be placed between the power supply area 222 and the other. These can determine the values of circuits around the power supply area 222 at power supply restoration so as to prevent the malfunction of the circuits around the power supply area 222.

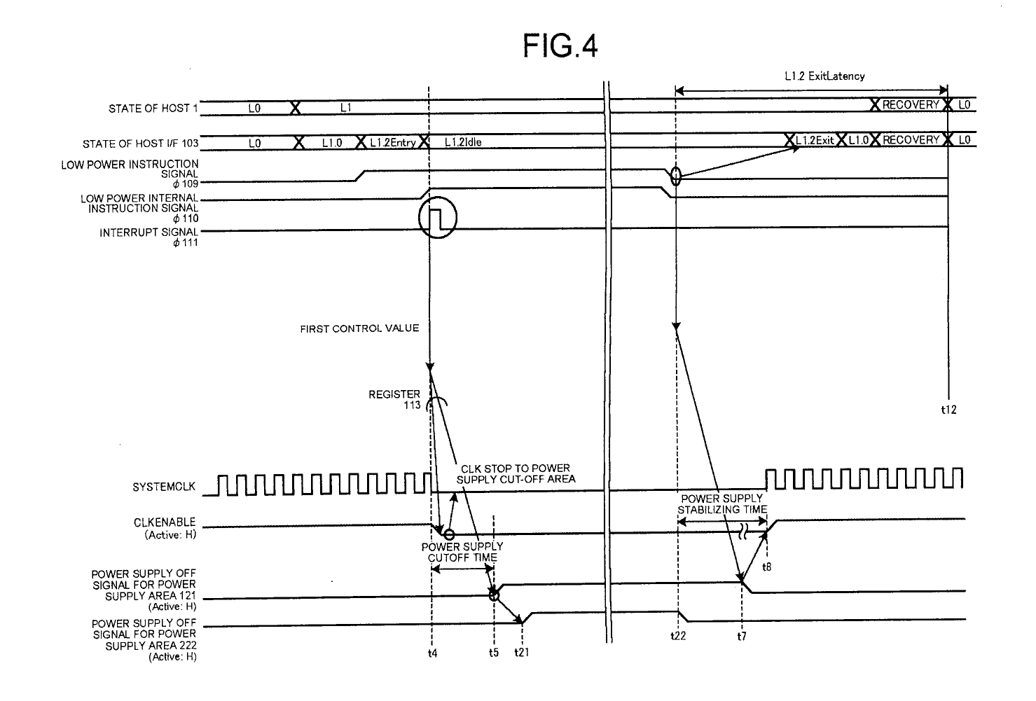

The memory system 200 operates differently from that of the first embodiment in the following points as shown in FIG. 4. FIG. 4 is a timing chart showing the operation of the memory system 200.

At timing t4, a clock stop to the host I/F 103 and the memory control circuit 116 is performed.

At timing t5, the power supply-CLK control circuit 204 makes the power supply OFF signal for the power supply area 121 transition from “L” to “H” according to the power shutdown time having elapsed. Thus, power supply from the power supply circuit 118 to the host I/F 103 is shut down. That is, a power shutdown to the host I/F 103 is performed.

At timing t21, the power supply-CLK control circuit 204 makes the power supply OFF signal for the power supply area 222 transition from “L” to “H” according to power supply to the host I/F 103 being shut down. Thus, power supply from the power supply circuit 118 to the memory control circuit 116 is shut down. That is, a power shutdown to the memory control circuit 116 is performed.

At timing t22, the low power instruction signal φ109 transitions from “H” to “L”. This is an instruction from the host 1 to return from the low power state (L1.2 state) to the normal state (L0 state).

The power supply-CLK control circuit 204 receives the low power instruction signal φ109 of the non-active level (L level) from the host 1 via the wiring 109. The power supply-CLK control circuit 204 makes the power supply OFF signal for the power supply area 222 transition from “H” to “L” according to the low power instruction signal φ109 of the non-active level. Thus, power supply from the power supply circuit 118 to the memory control circuit 116 is restored. That is, power restoration to the memory control circuit 116 is performed.

At timing t7, the power supply-CLK control circuit 204 makes the power supply OFF signal for the power supply area 121 transition from “H” to “L” according to the low power instruction signal φ109 of the non-active level. Thus, power supply from the power supply circuit 118 to the host I/F 103 is restored. That s, power restoration to the host I/F 103 is performed.

At timing t8, clock resumption to the host I/F 103 and the memory control circuit 116 is performed.

As described above, in the second embodiment, the power supply-CLK control circuit 204 in the memory system 200 performs a clock stop and power shutdown to the host I/F 103 and the memory control circuit 116 according to the low power internal instruction signal instructing to reduce power. Thus, the power consumption of the memory system 200 in the low power consumption mode can be further reduced. That is, a clock stop and power shutdown to more power supply areas 121 and 222 than in the first embodiment can be performed, and hence the power of the entire memory system 200 can be reduced by about 80%, for example.

### Third Embodiment

Next, a memory system 300 according to the third embodiment will be described. Description will be made below focusing on the differences from the second embodiment.

While in the second embodiment power supply to the power supply area 121 corresponding to the entire host I/F 103 is shut down, in the third embodiment power supply to a power supply area 321 corresponding to part of a host I/F 303 is shut down.

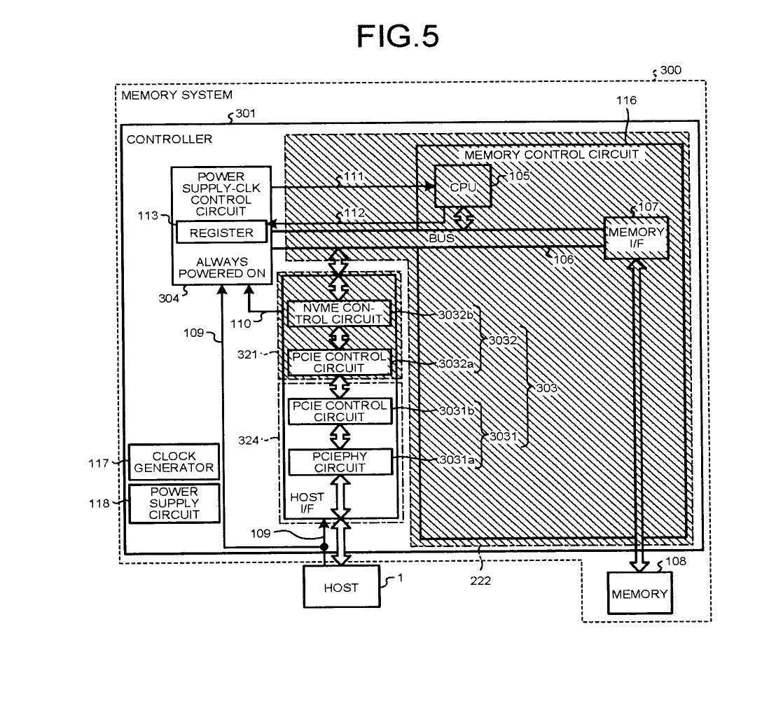

Specifically, as shown in FIG. 5, in a controller 301 of the memory system 300, a power supply-CLK control circuit 304 performs a clock stop and a power shutdown to part of the host I/F 303 and the memory control circuit 116 according to the low power internal instruction signal instructing to reduce power. FIG. 5 is a diagram showing the configuration of the memory system 300.

For example, the power supply-CLK control circuit 304 performs a clock stop and power shutdown to part of the host I/F 103 and the memory control circuit 116 according to the first control value being written into the register 113. That is, it performs a clock stop and power shutdown to each of the power supply areas 321 and 222 indicated by oblique hatching in FIG. 3.

Further, the power supply-CLK control circuit 304 performs power restoration and clock resumption to the host I/F 303 and the memory control circuit 116 according to the low power internal instruction signal instructing to restore.

For example, when receiving the low power instruction signal instructing to restore from the host 1, the power supply-CLK control circuit 304 performs power restoration to the memory control circuit 116 according to the low power instruction signal. Then the power supply-CLK control circuit 304 performs power restoration to the part of the host I/F 303 and clock resumption to the part of the host I/F 303 and the memory control circuit 116 according to the low power instruction signal.

More specifically, the host I/F 303 has a first portion 3031 and a second portion 3032. The second portion 3032 is placed between the first portion 3031 and the bus 106. The first portion 3031 is a part which interacts with the host 1 and corresponds to an always-powered-ON area 324. The second portion 3032 is a part corresponding to the power supply area 321 to which power supply is shut down. The always-powered-ON area 324 can be regarded as being the host. 1 side area of the host I/F 303, and the power supply area 321 can be regarded as being the bus 106 side area of the host I/F 303.

The first portion 3031 has a PCIEPHY circuit 3031a and a PCIE control circuit 3031b. The second portion 3032 has a PCIE control circuit 3032a and an NVME control circuit 3032b. The PCIE control circuit 3031b and PCIE control circuit 3032a inherently form one PCIE control circuit, but the part that interacts with the PCIEPHY circuit 3031a is named the PCIE control circuit. 3031b and provided in the always-powered-ON area 324.

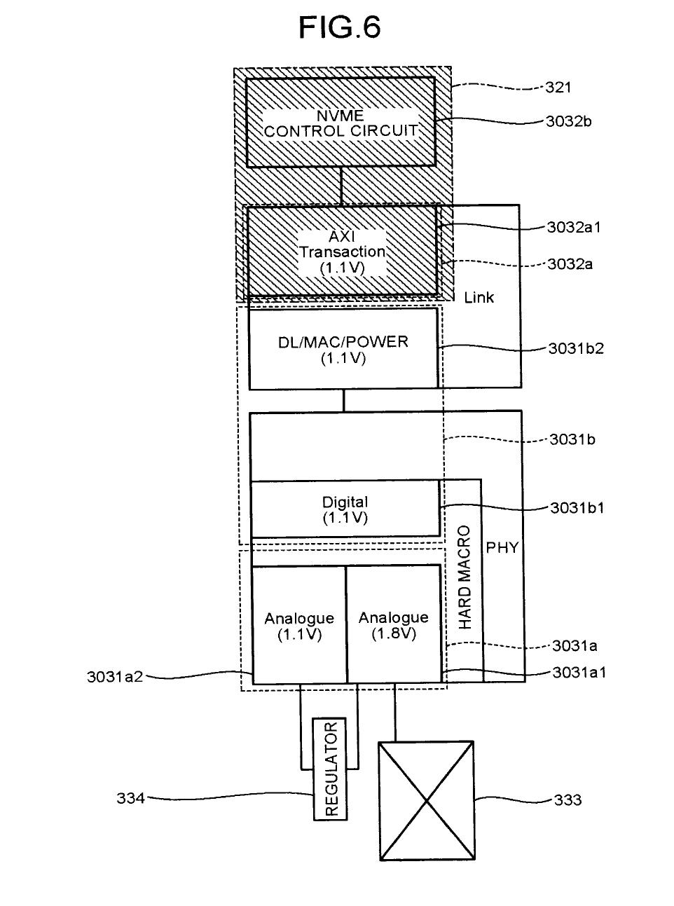

For example, as shown in FIG. 6, the first portion 3031 performs data conversion of the lower layer (physical layer, data link layer) than the second portion 3032, and the second portion 3032 performs data conversion of a higher layer (transaction layer) than the first portion 3031. That is, the host I/F 303 has an I/F configuration corresponding to the hierarchy of PCIExpress adapted for SSD use. FIG. 6 is a diagram showing the hardware configuration of the host I/F 303.

The PCIEPHY circuit 3031a has analog circuits 3031a1 and 3031a2. The analog circuit 3031a1 receives power supply V1 (e.g., 1.8 V) from the power supply circuit 118 via a terminal 333 to operate with power supply V1. The analog circuit 3031a2 is connected to the analog circuit 3031a1 via a regulator 334. The regulator 334 receives power supply V1 from the analog circuit 3031a1 and generates power supply V2 (e.g., 1.1 V) lower than power supply V1 to supply to the analog circuit 3031a2. The analog circuit 3031a2 receives power supply V2 from the regulator 334 to operate with power supply V2.

The PCIE control circuit 3031b has a digital circuit 3031b1 and a DL/MAC/POWER circuit 3031b2. The digital circuit 3031b1 and DL/MAC/POWER circuit 3031b2 receive power supply V2 (e.g., 1.1 V) from the power supply circuit 118 to operate with power supply V2.

For example, the digital circuit 3031b1 A/D converts the outputs of the analog circuits 3031a1 and 3031a2 to generate data and supplies the generated data to the DL/MAC/POWER circuit 3031b2. The DL/MAC/POWER circuit 3031b2 performs data conversion of the physical layer (MAC layer) and data conversion of the data link layer (DL layer) sequentially on the digital signal. The DL/MAC/POWER circuit 3031b2 outputs the data-converted data to the PCIE control circuit 3032a.

Or, for example, the DL/MAC/POWER circuit 3031b2 performs data conversion of the data link layer and data conversion of the physical layer sequentially on the output of the PCIE control circuit 3032a to output to the digital circuit 3031b1. The digital circuit 3031b1 A/D converts the output of the DL/MAC/POWER circuit 3031b2 to generate an analog signal and outputs the generated analog signal to the analog circuits 3031a1 and 3031a2.

The PCIE control circuit 3032a has an AXI Transaction circuit 3032a1. The AXI Transaction circuit 3032a1 receives power supply V2 (e.g., 1.1 V) from the power supply circuit 118 to operate with power supply V2.

For example, the AXI Transaction circuit 3032a1 performs data conversion of the transaction layer on the output of the DL/MAC/POWER circuit 3031b2. The AXI Transaction circuit 3032a1 outputs the data-converted data to the NVME control circuit 3032b.

Or, for example, the AXI Transaction circuit 3032a1 performs data conversion of the transaction layer on the output of the NVME control circuit 3032b. The AXI Transaction circuit 3032a1 outputs the data-converted data to the DL/MAC/POWER circuit 3031b2.

The NVME control circuit 3032b transfers the output of the AXI Transaction circuit 3032a1 to the bus 106 and transfers data transferred from the bus 106 to the AXI Transaction circuit 3032a1. The NVME control circuit 3032b receives power supply V2 (e.g., 1.1 V) from the power supply circuit. 118 to operate with power supply V2.

For example, the power supply-CLK control circuit 304 controls the power supply circuit 118 to shut down power supply to the AXI Transaction circuit 3032a1 and the NVME control circuit 3032b according to the first control value being written into the register 113. Thus, power supply to the AXI Transaction circuit 3032a1 and NVME control circuit 3032b is shut down as indicated by oblique hatching.

Further, the power supply-CLK control circuit 304 controls the power supply circuit 118 to restore power supply to the AXI Transaction circuit 3032a1 and the NVME control circuit 3032b according to the low power instruction signal φ109 of the active level. Thus, power supply to the AXI Transaction circuit 3032a1 and the NVME control circuit 3032b is restored.

It should be noted that it is desirable that at least part of the power supply area 321 (the second portion 3032) that holds an initial setting value be constituted by a retention F/F (or a retention SRAM) that holds the state before the power shutdown. With this constitution, on power supply restoration, the host I/F 303 can take over the setting value before the power shutdown to operate and hence does not need to perform initializing setting or the like on other registers and the like again after power supply restoration.

Further, it is desirable that cells to drive values after power supply restoration, called isolation cells, be placed between the power supply area 321 and the other. These can determine the values of circuits around the power supply area 321 at power supply restoration so as to prevent the malfunction of the circuits around the power supply area 321.

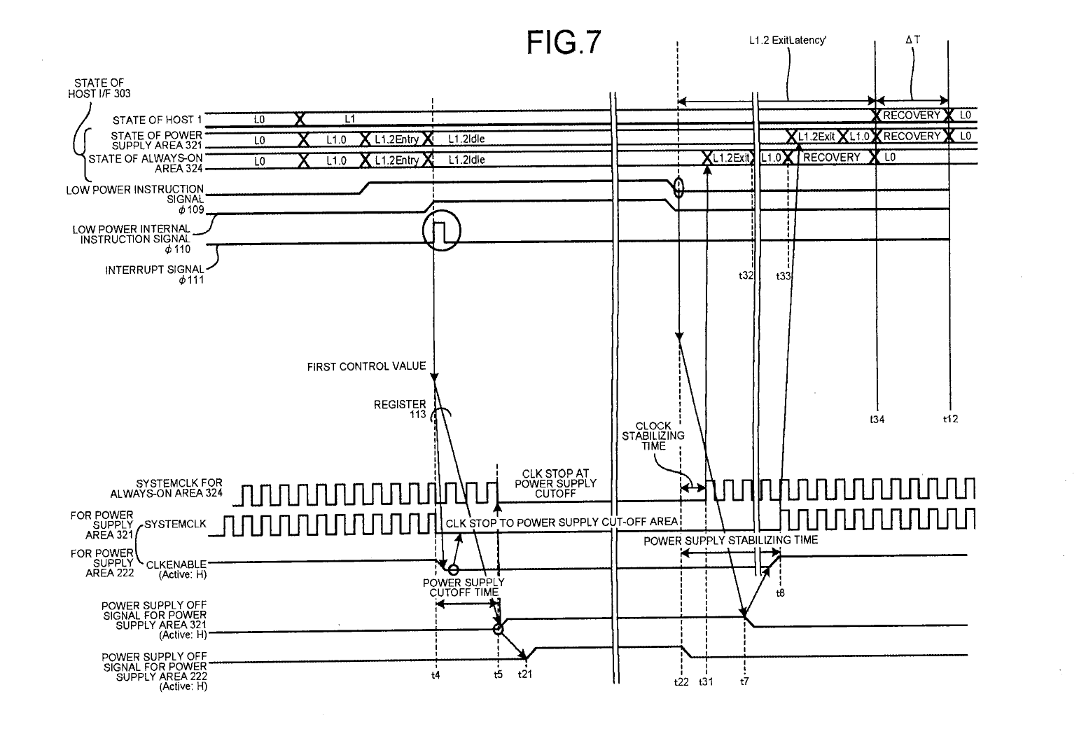

The operation of the memory system 300 differs from the second embodiment in the following points as shown in FIG. 7. FIG. 7 is a timing chart showing the operation of the memory system 300.

“STATE OF HOST I/F 303” is divided by the host I/F 303 into “STATE OF POWER SUPPLY AREA 321” and “STATE OF ALWAYS-ON AREA 324”, which are held in a state machine.

“SYSTEMCLK FOR ALWAYS-ON AREA 324” is an internal clock generated by the clock generator 117 and supplied to the always-ON area 324. “SYSTEMCLK FOR ALWAYS-ON AREA 324” is a high speed clock according to PCIE Standard.

“SYSTEMCLK FOR POWER SUPPLY AREA 321, POWER SUPPLY AREA 222” is an internal clock generated by the clock generator 117 and supplied to the power supply areas 321 and 222. “SYSTEMCLK FOR POWER SUPPLY AREA 321, POWER SUPPLY AREA 222” is a high speed clock according to PCIE Standard.

“CLKENABLE FOR POWER SUPPLY AREA 321, POWER SUPPLY AREA 222” is a clock enable signal supplied from the power supply-CLK control circuit 304 to the clock generator 117. “CLKENABLE FOR POWER SUPPLY AREA 321, POWER SUPPLY AREA 222” is a clock enable signal for the power supply area 321 and power supply area 222. “CLKENABLE FOR POWER SUPPLY AREA 321, POWER SUPPLY AREA 222” is an active high signal and is at the H level when instructing to supply the clock to each of the power supply areas 321 and 222 and at the L level when instructing to stop clock supply to each of the power supply areas 321 and 222.

At timing t4, a clock stop to the power supply areas 321 and 222 is performed. That is, a clock stop to the second portion 3032 and the memory control circuit 116 is performed.

At timing t5, the power supply-CLK control circuit 304 makes the power supply OFF signal for the power supply area 321 transition from “L” to “H” according to the power shutdown time having elapsed. Thus, power supply from the power supply circuit 118 to the power supply area 321 is shut down. That is, a power shutdown to the second portion 3032 is performed.

Further, the power supply-CLK control circuit 304 makes a clock enable signal for the always-ON area 324 (not shown) transition from “H” to “L” according to power supply to the second portion 3032 being shut down. Thus, supply of the clock SYSTEMCLK from the clock generator 117 to the always-ON area 324 is stopped. That is, a clock stop to the first portion 3031 is performed.

At timing t21, the power supply-CLK control circuit 304 makes the power supply OFF signal for the power supply area 222 transition from “L” to “H” according to power supply to the second portion 3032 being shut down. Thus, power supply from the power supply circuit 118 to the power supply area 222 is shut down. That is, a power shutdown to the memory control circuit 116 is performed.

At timing t22, the low power instruction signal φ109 transitions from “H” to “L”. This is an instruction from the host 1 to return from the low power state (L1.2 state) to the normal state (L0 state).

The power supply-CLK control circuit 304 receives the low power instruction signal φ109 of the non-active level (L level) from the host 1 via the wiring 109. The power supply-CLK control circuit 304 makes the power supply OFF signal for the power supply area 222 transition from “H” to “L” according to the low power instruction signal φ109 of the non-active level. Thus, power supply from the power supply circuit 118 to the power supply area 222 is restored. That is, power restoration to the memory control circuit 116 is performed.

Then the power supply-CLK control circuit 304 instructs to restore power supply to the host I/F 303 and to resume clock supply to the host I/F 303 and the memory control circuit 116 according to the low power instruction signal φ109 of the non-active level.

Further, the power supply-CLK control circuit 304 starts counting a clock stabilizing time at timing t22 using a counter (not shown). The clock stabilizing time has a predetermined time length (counter count value) in which clock supply can be resumed stably after the control circuit 304 instructs to resume clock supply. The clock stabilizing time is shorter than the power supply stabilizing time.

Further, at timing t31, the power supply-CLK control circuit 304 makes the clock enable signal for the always-ON area 324 (riot shown) transition from “L” to “H” according to the clock stabilizing time having elapsed. Thus, supply of the clock SYSTEMCLK from the clock generator 117 to the always-ON area 324 is resumed. That is, clock resumption to the first portion 3031 is performed.

Further, the host I/F 303 switches the state of the always-ON area 324 from the low power state (L1.2Idle state) to a first-stage transition state (L1.2Exit state) according to clock resumption to the first portion 3031. Thus, the always-ON area 324 goes out of the low power state (L1.2Idle state).

At timing t7, the power supply-CLK control circuit 304 makes the power supply OFF signal for the power supply area 321 transition from “H” to “L” according to the low power instruction signal φ109 of the non-active level. Thus, power supply from the power supply circuit 118 to the power supply area 321 is restored. That is, power restoration to the second portion 3032 is performed.

At timing t32, the host I/F 303 switches the state of the always-ON area 324 from the first-stage transition state (L1.2Exit state) to a second-stage transition state (L1.0 state).

At timing t8, clock resumption to the power supply areas 321 and 222 is performed. That is, clock resumption to the second portion 3032 and the memory control circuit 116 is performed.

At timing t33, the host I/F 303 switches the state of the always-ON area 324 from the second-stage transition state (L1.0 state) to a third-stage transition state (RECOVERY state).

At timing t34, the host I/F 303 switches the state of the always-ON area 324 from the third-stage transition state (RECOVERY state) to the normal state (L0 state).

It should be noted, because the first portion 3031 that interacts with the host 1 is restored at timing t34 as seen from the host 1, the memory system 300 can be regarded as being essentially restored at timing t34. Hence, a time L1.2 ExitLatency’ from timing t22 to timing t34 can be regarded as a restoration processing time from when an instruction to restore is received from the host 1 to when the memory system 300 finishes restoration. The restoration processing time in the third embodiment is made shorter by ΔT than the restoration processing time in the second embodiment (the time from timing t22 to timing t12).

For example, if the restoration processing time in the second embodiment is about 180 μs, the restoration processing time in the third embodiment can be shortened to about 105 μs. In this case, the time shortening effect for the restoration processing time is about 75 μs.

That is, in the host I/F 303, power supply to the first portion 3031 is continued even while power supply to the second portion 3032 is shut down, and hence when the host 1 instructs to restore with use of the low power instruction signal, after the clock stabilizing time shorter than the power supply stabilizing time elapses (at timing 31), the first portion 3031 can start operating to make its state transition. Thus, the restoration processing time from when an instruction to restore is received from the host 1 to when the memory system 300 finishes restoration can be shortened.

As described above, in the third embodiment, the power supply-CLK control circuit 304 in the memory system 300 performs a clock stop and power shutdown to part of the host I/F 303 and the memory control circuit 116 according to the low power internal instruction signal instructing to reduce power. For example, while the first portion 3031 of the host I/F 303 that interacts with the host 1 is always powered ON, a clock stop and power shutdown to the second portion 3032 placed between the first portion 3031 and the bus 106 is performed. Thus, when the low power instruction signal instructing to restore is received from the host 1, the memory system 300 can be quickly restored. That is, the restoration processing time from when an instruction to restore is received from the host 1 to when the memory system 300 finishes restoration can be shortened.

### Fourth Embodiment

Next, a memory system 400 according to the fourth embodiment will be described. Description will be made below focusing on the differences from the third embodiment.

While in the third embodiment power supply to the always-powered-ON area 324 on the host 1 side of the host I/F 303 is steadily continued, in the fourth embodiment power supply to the area on the host 1 side of the host I/F 303 can be partially shut down.

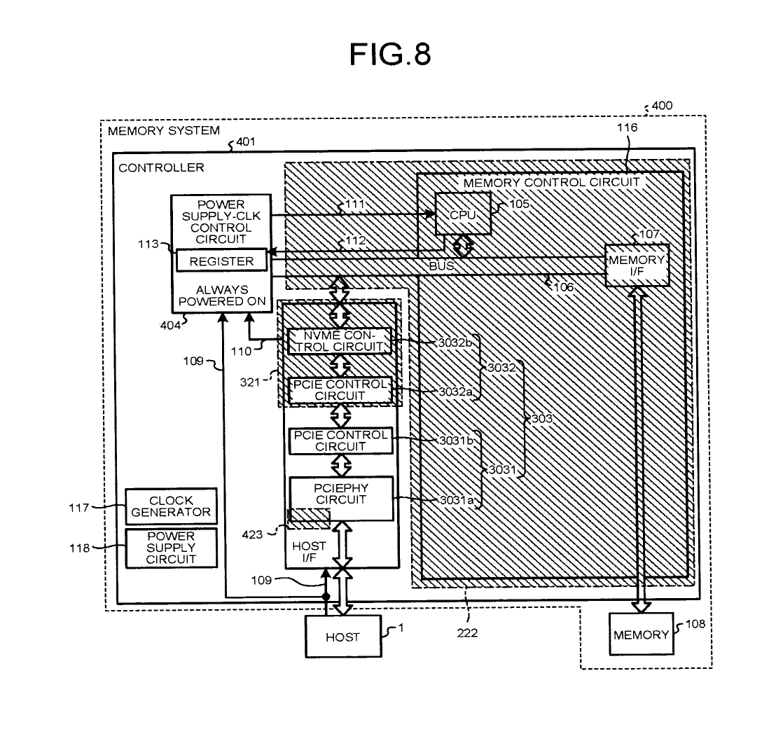

Specifically, as shown in FIG. 8, in a controller 401 of the memory system 400, a power supply-CLK control circuit 404 performs a clock stop and a power shutdown to part of the first portion 3031, the second portion 3032, and the memory control circuit 116 according to the low power internal instruction signal instructing to reduce power. FIG. 8 is a diagram showing the configuration of the memory system 400.

For example, the power supply-CLK control circuit 404 performs a clock stop and power shutdown to part of the first portion 3031, the second portion 3032, and the memory control circuit 116 according to the first control value being written into the register 113. That is, it performs a clock stop and power shutdown to each of the power supply areas 423, 321, and 222 indicated by oblique hatching in FIG. 8.

Further, the power supply-CLK control circuit 404 performs power restoration and clock resumption to the host I/F 303 and the memory control circuit 116 according to the low power internal instruction signal instructing to restore.

For example, when receiving the low power instruction signal instructing to restore from the host 1, the power supply-CLK control circuit 404 performs power restoration to the memory control circuit 116 according to the low power instruction signal. Then the power supply-CLK control circuit 404 performs power restoration to the part of the first portion 3031 and the second portion 3032 and clock resumption to the part of the first portion 3031, the second portion 3032, and the memory control circuit 116 according to the low power instruction signal.

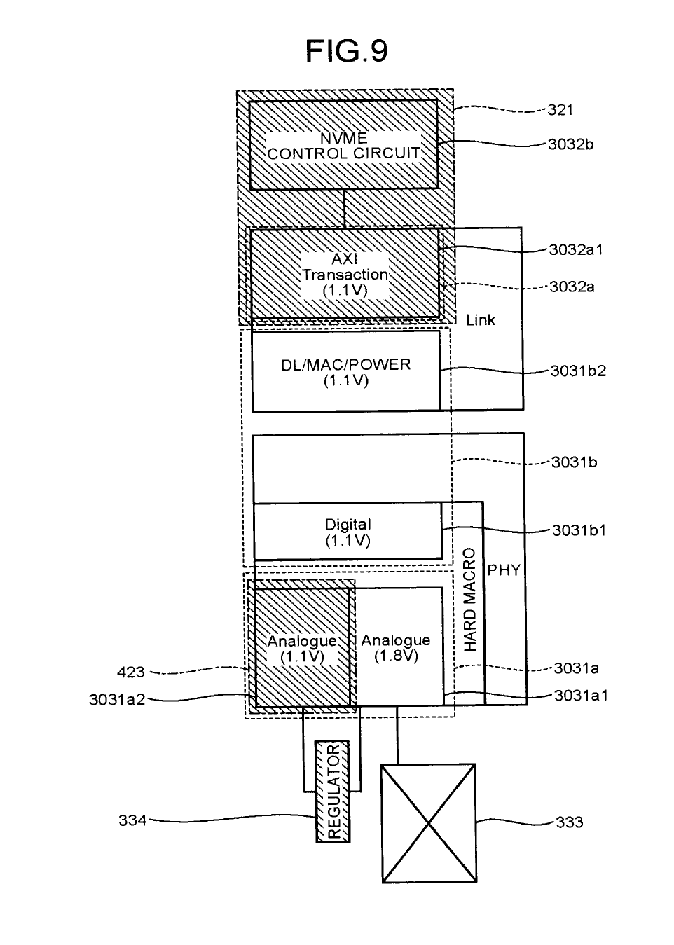

More specifically, as shown in FIG. 9, the power supply area 423 includes an analog circuit 3031a2. The power supply area 321 includes a PCIE control circuit 3032a (AXI Transaction circuit 3032a1) and an NVME control circuit 3032b. The analog circuit (second circuit) 3031a2 is connected to an analog circuit (first circuit) 3031a1 always powered ON via a regulator 334. Hence, at power supply restoration, the analog circuit 303122 can be restored in a short time.

For example, the power supply-CLK control circuit 404 controls the power supply circuit 118 to shut down power supply to the AXI Transaction circuit 3032a1 and the NVME control circuit 3032b according to the first control value being written into the register 113 and simultaneously makes the regulator 334 stop operating. Thus, power supply to the analog circuit 3031a2, AXI Transaction circuit 3032a1, and NVME control circuit 3032b is shut down as indicated by oblique hatching.

Further, the power supply-CLK control circuit 404 controls the power supply circuit 118 to restore power supply to the AXI Transaction circuit 3032a1 and the NVME control circuit 3032b according to the low power instruction signal φ109 of the non-active level and simultaneously makes the regulator 334 resume operating. Thus, power supply to the analog circuit 3031a2, AXI Transaction circuit 3032a1, and NVME control circuit 3032b is restored.

As described above, in the fourth embodiment, the power supply-CLK control circuit 404 in the memory system 400 performs a clock stop and power shutdown to part of the first portion 3031, the second portion 3032, and the memory control circuit 116 according to the low power internal instruction signal instructing to reduce power. That is, a clock stop and power shutdown to the power supply areas 321, 222, and 423 is performed. Thus, power supply to the power supply area 423 (part of PCIEPHY circuit 3031a) can also be shut down compared with the third embodiment, so that power consumption can be further lowered as compared with the third embodiment.

### Fifth Embodiment

Next, a memory system 500 according to the fifth embodiment will be described. Description will be made below focusing on the differences from the fourth embodiment.

While in the fourth embodiment power supply to the power supply area 423 on the host 1 side of the host I/F 303 can be shut down, in the fifth embodiment power supply to more power supply areas 423, 524 on the host 1 side of the host I/F 303 can be shut down.

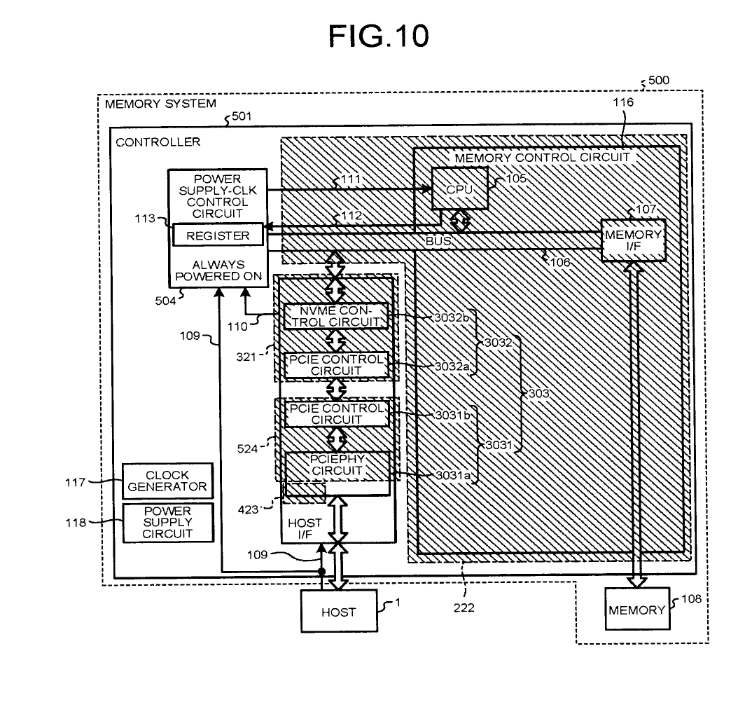

Specifically, as shown in FIG. 10, in a controller 501 of the memory system 500, a power supply-CLK control circuit 504 performs a clock stop and a power shutdown to most part of the first portion 3031, the second portion 3032, and the memory control circuit 116 according to the low power internal instruction signal instructing to reduce power. FIG. 10 is a diagram showing the configuration of the memory system 400.

For example, the power supply-CLK control circuit 504 performs a clock stop and power shutdown to most part of the first portion 3031, the second portion 3032, and the memory control circuit 116 according to the first control value being written into the register 113. That is, it performs a clock stop and power shutdown to each of the power supply areas 423, 524, 321, and 222 indicated by oblique hatching in FIG. 10. In FIG. 10, the power supply area 524 covers the PCIE control circuit 3031b side of the PCIEPHY circuit 3031a as well, which means that power supply to the interface part of the PCIEPHY circuit 3031a with the PCIE control circuit 3031b is also shut down.

Further, the power supply-CLK control circuit 504 performs power restoration and clock resumption to the host I/F 303 and the memory control circuit 116 according to the low power internal instruction signal instructing to restore.

For example, when receiving the low power instruction signal instructing to restore from the host 1, the power supply-CLK control circuit 504 performs power restoration to the memory control circuit 116 according to the low power instruction signal. Then the power supply-CLK control circuit 504 performs power restoration to the most part of the first portion 3031 and the second portion 3032 and clock resumption to the most part of the first portion 3031, the second portion 3032, and the memory control circuit 116 according to the low power instruction signal.

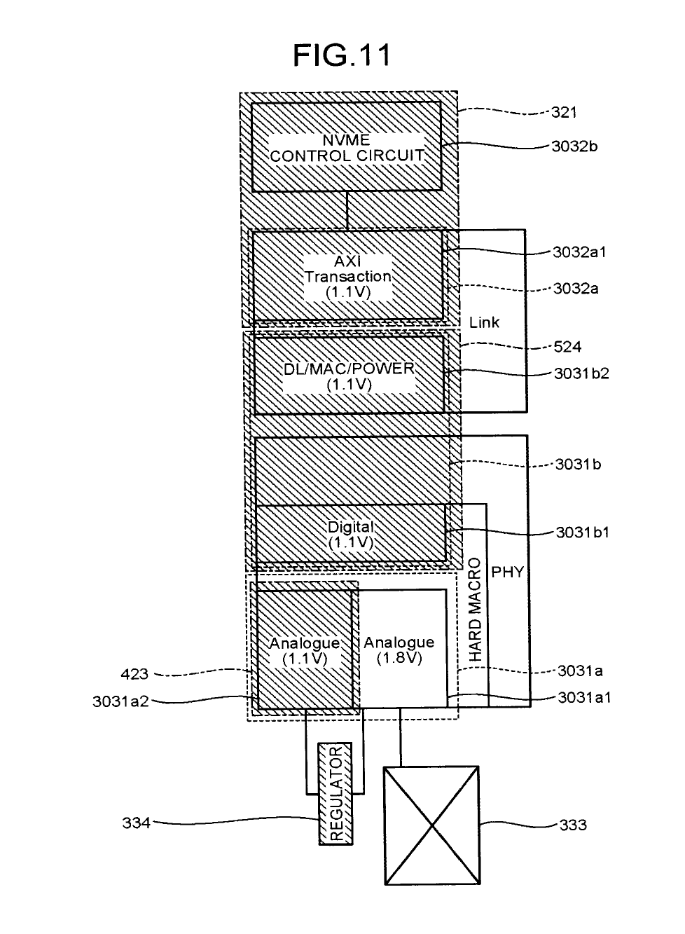

More specifically, as shown in FIG. 11, the power supply area 423 includes an analog circuit 3031a2. The power supply area 524 includes the PCIE control circuit 3031b (the digital circuit 3031b1, DL/MAC/POWER circuit 3031b2). The power supply area 321 includes a PCIE control circuit 3032a (AXI Transaction circuit 3032a1) and an NVME control circuit 3032b. The analog circuit 3031a2 is connected to an analog circuit 3031a1 always powered ON via a regulator 334. Hence, at power supply restoration, the analog circuit 3031a2 can be restored in a short time.

For example, the power supply-CLK control circuit 504 controls the power supply circuit 118 to shut down power supply to the digital circuit 3031b1, DL/MAC/POWER circuit 3031b2, AXI Transaction circuit 3032a1, and NVME control circuit 3032b according to the first control value being written into the register 113 and simultaneously makes the regulator 334 stop operating. Thus, power supply to the analog circuit 3031a2, digital circuit (third circuit) 3031b1, DL/MAC/POWER circuit (third circuit) 3031b2, AXI Transaction circuit 3032a1, and NVME control circuit 3032b is shut down as indicated by oblique hatching. Note that the digital circuit 3031b1 and DL/MAC/POWER circuit 3031b2 are placed between the analog circuit 3031a and the second portion 3032.

Further, the power supply-CLK control circuit 504 controls the power supply circuit 118 to restore power supply to the digital circuit 3031b1, DL/MAC/POWER circuit 3031b2, AXI Transaction circuit 3032a1, and NVME control circuit 3032k according to the low power instruction signal φ109 of the non-active level and simultaneously makes the regulator 334 resume operating. Thus, power supply to the analog circuit 3031a2, digital circuit 3031b1, DL/MAC/POWER circuit 3031b2, AXI Transaction circuit 3032a1, and NVME control circuit 3032b is restored.

As described above, in the fifth embodiment, the power supply-CLK control circuit 504 in the memory system 400 performs a clock stop and power shutdown to most part of the first portion 3031, the second portion 3032, and the memory control circuit 116 according to the low power internal instruction signal instructing to reduce power. For example, while the analog circuit 3031a1 of the first portion 3031 is always powered ON, a clock stop and power shutdown to the other part than the analog circuit 3031a1 of the first portion 3031, the second portion 3032, and the memory control circuit 116 is performed. Thus, power consumption can be further lowered as compared with the fourth embodiment. That is, the power consumption of the memory system 500 in the low power consumption mode can be further reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A controller comprising:
a memory control circuit that controls a nonvolatile semiconductor memory;
a host interface that performs data-format conversion between data of a host and data of the memory control circuit and generates an internal signal according to a low power instruction signal received from the host;
a power control circuit that performs at least one of a clock stop and a power shutdown to a power supply area including at least part of the host interface according to the internal signal received from the host interface and performs, to the power supply area, at least one of a power restoration and a clock resumption according to the low power instruction signal received from the host.

2. The controller according to claim 1, wherein
the host interface generates the internal signal instructing to reduce power according to the low power instruction signal instructing to reduce power and supplies the generated internal signal to the power control circuit, and
the power control circuit performs, to the power supply area, at least one of a clock stop and a power shutdown according to the internal signal instructing to reduce power.

3. The controller according to claim 2, wherein
the host interface generates the internal signal according to progress status of data transfer processing in the host interface.

4. The controller according to claim 3, wherein
the host interface generates the internal signal instructing to reduce power according to data transfer processing having finished in the host interface and supplies to the power control circuit.

5. The controller according to claim 3, wherein
after receiving the low power instruction signal instructing to reduce power from the host, the host interface generates the internal signal instructing to reduce power according to data transfer processing in the host interface having finished and supplies the generated internal signal to the power control circuit.

6. The controller according to claim 1, wherein
the power control circuit is configured to be able to receive the low power instruction signal from the host while power supply to the power supply area is shut down.

7. The controller according to claim 6, wherein
the power control circuit performs, to the power supply area, at least one of a power restoration and a clock resumption according to the low power instruction signal instructing to restore.

8. The controller according to claim 1, wherein
the power supply area includes the host interface.

9. The controller according to claim 8, wherein
the power control circuit supplies an interrupt signal to the memory control circuit according to the internal signal instructing to reduce power,
wherein the memory control circuit writes a first control value to instruct to perform at least one of a clock stop and a power shutdown into a register in the power control circuit according to the interrupt signal, and
wherein the power control circuit performs, to the host interface, at least one of a clock stop and a power shutdown according to the first control value written.

10. The controller according to claim 9, wherein
the power control circuit performs, to the host interface, at least one of a power restoration and a clock resumption according to the low power instruction signal instructing to restore.

11. The controller according to claim 1, wherein
the power supply area includes the host interface and the memory control circuit.

12. The controller according to claim 11, wherein
the power control circuit supplies an interrupt signal to the memory control circuit according to the internal signal instructing to reduce power,
wherein the memory control circuit writes a first control value to instruct to perform at least one of a clock stop and a power shutdown into a register in the power control circuit according to the interrupt signal, and
wherein the power control circuit performs, to the host interface, at least one of a clock stop and a power shutdown and the memory control circuit according to the first control value written.

13. The controller according to claim 12, wherein
the power control circuit performs, to the host interface and the memory control circuit, at least one of a power restoration and a clock resumption according to the low power instruction signal instructing to restore.

14. The controller according to claim 1, wherein
the host interface has:
a first portion; and
a second portion placed between the first portion and a bus,
wherein the power supply area includes the second portion and the memory control circuit.

15. The controller according to claim 14, wherein
the second portion performs data-format conversion of a higher layer than the first portion.

16. The controller according to claim 1, wherein
the host interface has:
a first portion; and
a second portion placed between the first portion and a bus,
wherein the power supply area includes part of the first portion, the second portion, and the memory control circuit.

17. The controller according to claim 16, wherein
the first portion has:
a first circuit; and
a second circuit connected to the first circuit via a regulator,
wherein the power control circuit performs, to the second circuit, the second portion, and the memory control circuit, at least one of a clock stop and a power shutdown.

18. The controller according to claim 1, wherein
the host interface has:
a first portion; and
a second portion placed between the first portion and a bus,
wherein the power supply area includes most part of the first portion, the second portion, and the memory control circuit.

19. The controller according to claim 18, wherein
the first portion has:
a first circuit;
a second circuit connected to the first circuit via a regulator; and
a third circuit placed between the first circuit and the second portion,
wherein the power control circuit performs, to the second circuit, the third circuit, the second portion, and the memory control circuit, at least one of a clock stop and a power shutdown.

20. A memory system comprising:
a nonvolatile semiconductor memory; and
a controller according to claim 1 that controls the nonvolatile semiconductor memory.
